(19) United States
(12) Patent Application Publication
(10) Pub. No.: US 2022/0077832 A1
(43) Pub. Date: Mar. 10, 2022

(54) AMPLIFIER FOR A CONTACTLESS ELECTROMETER AND FEEDBACK CIRCUIT

(71) Applicant: EEGNOSIS LIMITED LIABILITY COMPANY, Moscow (RU)

(72) Inventor: Oleg BELOV, Moscow (RU)

(73) Assignee: EEGNOSIS LIMITED LIABILITY COMPANY, Moscow (RU)

(21) Appl. No.: 17/417,245

(22) PCT Filed: Nov. 21, 2019
(86) PCT No.: PCT/RU2019/000838

§ 371 Date: Jun. 22, 2021

(30) Foreign Application Priority Data
Dec. 27, 2018 (RU) 2018147058

(51) Int. Cl. H03F 3/45; H03F 1/26; H03F 3/185

(52) U.S. Cl. CPC H03F 3/45475; H04R 3/00; H03F 3/185; H03F 1/26

(57) ABSTRACT

An amplifier of a contactless electrometer, having feedback comprising an inverting integrator which is connected to the booster output, two series-connected p-n junctions connected by a common point thereof to the booster input, and a circuit for biasing the two series-connected p-n junctions in the reverse direction, wherein the mid point of the biasing circuit is connected to the output of the inverting integrator.

### TECHNICAL FIELD

This invention relates to electrical measurements, and more particular to recording and measuring an object's surface electrical potential variations, e.g. in electroencephalography.

### BACKGROUND

It is known that, while direct current amplifiers are used together with an isolating capacitance as in a contactless electrometer, zero bias voltage produced by a direct current feedback should be applied to the amplifier input. However, a feedback circuit comprised of resistors is unsuitable for amplifying weak signals due to unacceptably high thermal noise from the resistors.

U.S. Pat. No. 9,559,647 dated Jan. 31, 2017 discloses a feedback amplifier, comprising an inverting integrator connected to the amplifier output and two series-connected pn-junctions connected, at their common point, to the amplifier input, and, accordingly, an amplifier feedback circuit comprising an integrator connectable to the amplifier output and two series-connected pn-junctions (diodes) connectable, at their common point, to the amplifier input. Said known amplifier and feedback loop are the prior art closest to the technical solutions of the present invention.

The amplifier as disclosed in U.S. Pat. No. 9,559,647 dated Jan. 31, 2017 is configured to amplify a signal of a capacitive transducer operating in a largely similar way to that of a potential difference sensor (electrometer). Said prior art solutions use two anti-parallel diodes, while the direct component stabilization is provided by applying zero bias voltage with the use of an integrator comprised of a transconductance amplifier and a capacitor. Noise attenuation is provided by a high dynamic resistance of the pn-junction with no bias (zero bias) applied.

However, the prior art amplifier is configured to amplify a microphone signal, but not to amplify relatively weaker signals (of a few microvolts) of brain electrical activity in a frequency range from fractions of Hz to a few Hz. Therein, noise attenuation achieved by the prior art amplifier and by using the prior art feedback circuit is insufficient.

### SUMMARY OF THE INVENTION

A technical result provided by the contactless electrometer amplifier of the present invention and by using the contactless electrometer amplifier feedback circuit of the present invention is substantially smaller amplifier noise.

The technical result is achieved by a non-contact electrometer amplifier configured with a feedback circuit, comprising: an inverting integrator connected to the amplifier output, two series-connected PN junctions connected, at their common point, to the amplifier input, and a circuit for reverse biasing the two series-connected pn-junctions, the biasing circuit midpoint being connected to the inverting integrator output.

The inverting integrator in the feedback circuit may be connected to the biasing circuit midpoint via an analog adder having its second input connected to the amplifier output. The analog adder second input may be connected to the amplifier output via a high pass filter.

The technical result is achieved by using a contactless electrometer amplifier feedback circuit, comprising: an inverting integrator having an input connected to the amplifier output, and two series-connected pn-junctions (such as, diodes or transistors) connected, at their common point, to the amplifier input, the two junctions being reverse biased, and the inverting integrator output is connected to the pn-junction reverse biasing circuit midpoint.

Smaller noise is a result of very high dynamic impedance of the both reverse biased series-connected pn-junctions, i.e. by using an active area in the reverse bias region of the volt-ampere characteristic of pn-junctions.

Because of inevitably different parameters of the pn-junctions a zero bias occurs at the amplifier output, and an integrator should be used in the feedback circuit to apply (zero bias) voltages for correction of the amplifier output zero biasing and to ensure that zero is restored slowly enough to not significantly disturb the amplitude/frequency response of the amplifier in the operating range.

### BRIEF DESCRIPTION OF THE DRAWINGS

FIG. 1 shows a block diagram of a biopotential measuring electrometer in a first embodiment.

FIG. 2 shows a block diagram of a biopotential measuring electrometer in a second embodiment.

FIG. 3 shows a block diagram of a biopotential measuring electrometer in a third embodiment.

FIG. 4 shows an embodiment of an amplifier schematic diagram.

### DETAILED DESCRIPTION OF EMBODIMENTS

Where surface biopotential variations are measured with a contactless electrometer, an isolating capacitance is formed (between an electrode and the skin surface), which may not be less than tens of picofarad, while the explored frequency range starts from fractions of Hertz. Hence, the time constant of a filter formed by the isolating capacitance and the amplifier resistance should be about one second, which requires an input resistance to be about tens of GigaOhms. The amplifier ground is assumed to be connected to the subject (body), i.e. it is assumed that there is a common point and, thus, the potential of the electrometer electrode is not far from the mean potential of the skin. However, leakage current can produce a DC offset at the isolating capacitance, substantial enough to prevent measurements.

The object is to keep DC voltage on the isolating capacitance extremely small, because otherwise any variations in this capacitance produced by vibrations or other external effects, would cause the variations of the voltage at the isolating capacitance, thus producing the so called ‘microphonic effect’. A measured signal produced by biopotential measurement has a value of a few microvolts, while the capacitance may vary by several percentage points. Therefore, for an accurate biopotential measurement, it is necessary that the isolating capacitance DC voltage should not be higher than tens or even a few microvolts.

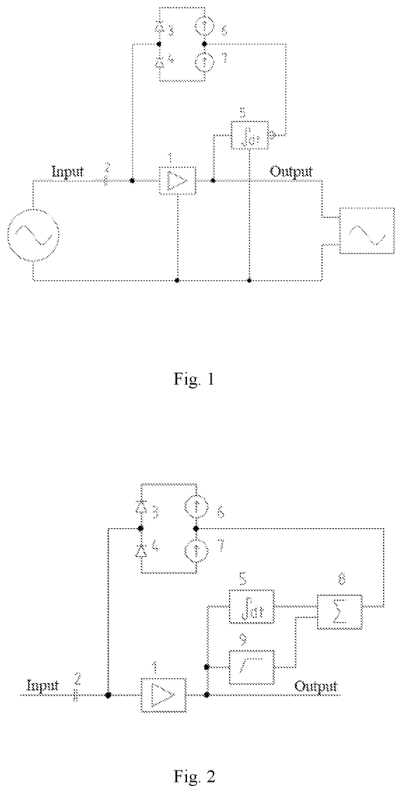

FIG. 1 shows a block diagram of a feedback amplifier for an electrometer, the amplifier comprising: a non-inverting direct current amplifier 1 connected to an isolating capacitance 2 which is formed between an electrode and a subject when the electrometer is in use, two series-connected pn-junctions 3 and 4, an inverting integrator 5, and two voltage level biasing circuits 6 and 7. The integrator 5 input is connected to the amplifier 1 output, while its output, via the voltage level biasing circuits 6 and 7, is connected to two series-connected pn-junctions 3 and 4 such as to reverse bias the pn-junctions, the common point of the pn-junctions 3 and 4 being connected to the amplifier 1 input.

The direct component of the amplifier input voltage is determined by the balance of the pn-junctions reverse currents and the amplifier input current. Where a direct offset is present at the amplifier output, caused either by leakage currents or the capacitor 2 charge resulting from a pulse interference, the integrator output voltage is changing slowly, as compared with the operating range frequencies, until the pn-junctions reverse currents compensate each other and the amplifier input current in a point of zero voltage at the amplifier input.

The integrator, as shown in FIG. 2, is connected to the biasing circuit midpoint via an analog adder 8 having its second input connected to the amplifier output via a high pass filter 9. The adder and the filter parameters should be selected such that, in the operating frequency range, the voltage at the voltage level biasing circuits 6, 7 and at the ends of the pn-junctions 3 and 4 connected thereto replicates the amplifier 1 input voltage. Such solution provides a constant bias at the pn-junctions within a wide range of input signals, thus reducing harmonic distortions. Furthermore, since the pn-junctions 3 and 4 voltage variation during input signal amplification is substantially lower than that signal, with such solution, the pn-junction capacitance influence may be compensated, thus reducing the amplifier input capacitance in the operating frequency range, and therefor the sensor gain may be more predictable. Time constants of the integrator, the filter and the circuit formed by the input capacitance 2 and the dynamic resistance of the junctions 3 and 4 are in accordance with each other to ensure stability of the amplifier covered by the feedback circuit.

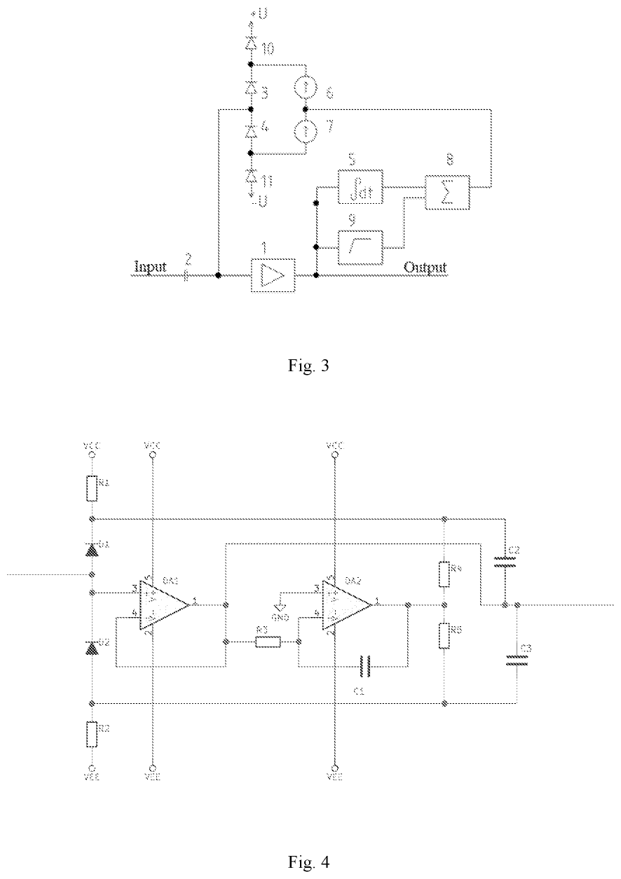

The solution according to the present invention may be supplemented with the protection circuits against overload or electrostatic discharge applied to the amplifier input, as shown in FIG. 3. Herein, the circuit is configured with additional diodes 10 and 11 connected to a primary or an auxiliary power supply. Such solution is advantageous over individual protection circuits, normally integrated into the amplifier 1, and when the proposed solution is implemented in the same chip as the amplifier 1, the extra protection diodes may be excluded and the amplifier input capacitance may be reduced.

FIG. 4 shows an embodiment of the amplifier. Therein, an inverting integrator is comprised by an operational amplifier DA2, a resistor R3 and a capacitor C1 with the level biasing, adding and signal filtering operations done by the units 6, 7, 8, 9 of the block diagram of FIG. 2 being performed by the circuits R1, R4, C2 and R2, R5, C3.

1. A contactless electrometer amplifier configured with a feedback circuit, comprising: an inverting integrator connected to the amplifier output and two series-connected pn-junctions connected, at their common point, to the amplifier input, characterized in that it comprises a circuit for reverse biasing the two series-connected pn-junctions with the biasing circuit midpoint being connected to the inverting integrator output.

2. The amplifier of claim 1, wherein the inverting integrator is connected to the biasing circuit midpoint via an analog adder having its second input connected to the amplifier output.

3. The amplifier of claim 2, wherein the analog adder second input is connected to the amplifier output via a high pass filter.

4. A contactless electrometer amplifier feedback circuit, comprising: an inverting integrator having an input connected to the amplifier output and two series-connected pn-junctions connected, at their common point, to the amplifier input, wherein the two pn-junctions are reverse biased, and the inverting integrator output is connected to the pn-junction biasing circuit midpoint.
